(19) United States
(12) Patent Application Publication
(10) Pub. No.: US 2024/0322274 A1
(43) Pub. Date: Sep. 26, 2024

(54) Method for determining State of Charge of battery module and portable electronic device utilizing the same

(71) Applicant: MEDIATEK INC., Hsin-Chu (TW)

(72) Inventors: Jia-You Chuang, Hsinchu City (TW); Jui-Chi Wu, Hsinchu City (TW); Chi-Cheng Liao, Hsinchu City (TW)

(73) Assignee: MEDIATEK INC., Hsin-Chu (TW)

(21) Appl. No.: 18/124,572

(22) Filed: Mar. 21, 2023

(51) Int. Cl. H01M 10/48; G01R 31/36; H01M 50/204

(52) U.S. Cl. CPC H01M 10/482; G01R 31/36; H01M 50/204; H01M 2220/30

(57) ABSTRACT

A method for determining a State of Charge of a battery module with a first battery having a first rated capacity and a second battery having a second rated capacity including determining an adjusted rated capacity according to at least one of property data of the first battery, property data of the second battery and a system requirement, wherein the adjusted rated capacity is smaller than a summation of the first rated capacity and the second rated capacity; and determining a State of Charge (SoC) which indicates a level of charge of the battery module relative to a total capacity of the battery module according to the level of charge of the battery module and the adjusted rated capacity.

### BACKGROUND

Along with the application of mobile phone being popularize, the mobile phone becomes the necessity of people's life, and the function of mobile phone is also more and more abundance. In a conventional mobile phone conceptual design, a mobile phone is only equipped with one battery. When this piece of battery electric quantity depletes, the mobile phone cannot work and has to be charged. But when the user goes on business out of doors or in some places without power supplier, it will cause inconvenience to phone charging. Therefore, a concept of equipping dual-battery in a mobile phone presents.

In addition, for some newly developed foldable mobile phones, in order to balance the weight of the phone on both sides of the folding line, two batteries are equipped with each being located on one side of the folding line. These two batteries form a power supplying system of the mobile phone.

However, the two batteries equipped in one mobile phone may not have identical property, resulting in different discharging speeds. Therefore, how to estimate the residual battery capacity of the power supplying system of a mobile device having more than one battery becomes an issue to be concerned. Especially, when the batteries of the mobile phone are discharged by a fixed loading, how to determine the State of Charge (SoC) of the mobile phone to make the decreasing of residual battery capacity to be presented to the user in a linearly manner, even when the battery voltage is approaching the level to trigger a power-off of the mobile device, is an issue worthy to be concerned.

### SUMMARY

According to an embodiment of the invention, a portable electronic device comprises a battery module and a processor. The battery module comprises a first battery having a first rated capacity and a second battery having a second rated capacity. The processor is coupled to the battery module and configured to perform operations comprising: determining an adjusted rated capacity according to at least one of property data of the first battery, property data of the second battery and a system requirement, wherein the adjusted rated capacity is smaller than a summation of the first rated capacity and the second rated capacity; and determining a State of Charge (SoC) which indicates a level of charge of the battery module relative to a total capacity of the battery module according to the level of charge of the battery module and the adjusted rated capacity.

According to another embodiment of the invention, a method for determining a State of Charge (SoC) of a battery module comprised in a portable electronic device, wherein the battery module comprises a first battery having a first rated capacity and a second battery having a second rated capacity, and the method comprises: determining an adjusted rated capacity according to at least one of property data of the first battery, property data of the second battery and a system requirement, wherein the adjusted rated capacity is smaller than a summation of the first rated capacity and the second rated capacity; and determining a State of Charge (SoC) which indicates a level of charge of the battery module relative to a total capacity of the battery module according to the level of charge of the battery module and the adjusted rated capacity.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows an exemplary block diagram of a portable electronic device according to an embodiment of the invention.

FIG. 2 shows an exemplary block diagram of a modem according to an embodiment of the invention.

FIG. 3 shows an exemplary flow chart of a method for determining the SoC of the battery module comprised in the portable electronic device according to a first embodiment of the invention.

FIG. 4 is a table showing the exemplary property data of the batteries Bat_1 and Bat_2 according to an embodiment of the invention.

FIG. 5 shows an exemplary flow chart of a method for determining the SoC of the battery module comprised in the portable electronic device according to the second embodiment of the invention.

FIG. 6 is a schematic diagram showing the SoC determined by applying the proposed method under different temperature and service life conditions according to an embodiment of the invention.

### DETAILED DESCRIPTION

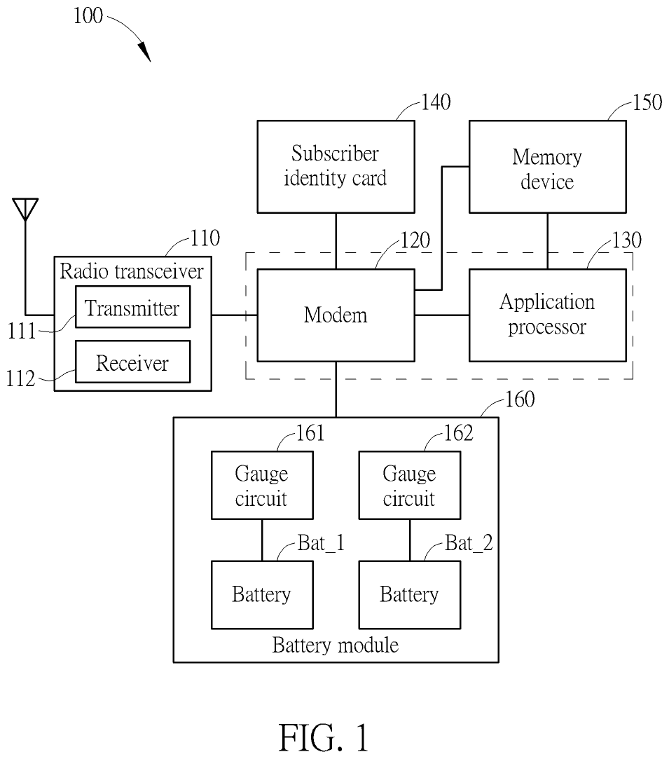

FIG. 1 shows an exemplary block diagram of a portable electronic device according to an embodiment of the invention. The portable electronic device 100 may be a communication apparatus, such as a Mobile Station (MS, which may be interchangeably referred to as User Equipment (UE)). The portable electronic device 100 may comprise at least an antenna module comprising at least one antenna, a radio transceiver 110, a modem 120, an application processor 130, a subscriber identity card 140, a memory device 150 and a battery module 160. The radio transceiver 110 may be configured to transmit and/or receive wireless signals to and/or from a network device in a wireless network via the antenna module, so as to communicate with the network device via a communication link established between the portable electronic device 100 and the network device. The radio transceiver 110 may comprise a receiver 112 configured to receive wireless signals from the air interface and a transmitter 111 configured to transmit wireless signals to the air interface, and the radio transceiver 110 may be further configured to perform RF signal processing. For example, the receiver 112 may convert the received signals into intermediate frequency (IF) or baseband signals to be processed, or transmitter 111 may receive the IF or baseband signals from the modem 120 and convert the received signals into wireless signals to be transmitted to the network device in the wireless network or in an access network (e. g. a cellular network or a wireless local access network). According to an embodiment of the invention, the network device may be a cell, a node B, an evolved node B (eNB), a g node B (gNB), a base station, a Mobility Management Entity (MME), an Access and Mobility Management Function (AMF) device, an access point (AP), etc., at the network side and communicating with the portable electronic device 100 by the wireless signals via the communication link.

The transmitter 111 and the receiver 112 of the radio transceiver 110 may comprise a plurality of hardware devices to perform radio frequency (RF) conversion and RF signal processing. For example, the transmitter 111 and/or the receiver 112 may comprise a power amplifier for amplifying the RF signals, a filter for filtering unwanted portions of the RF signals and/or a mixer for performing radio frequency conversion. According to an embodiment of the invention, the radio frequency may be, for example, the frequency of any specific frequency band for a LTE system, or the frequency of any specific frequency band for a 5G NR system or any wireless communication system under development, or the frequency of any specific frequency band for a WiFi system, or the likes.

The modem 120 may be configured to handle corresponding communications protocol operations and processing the IF or baseband signals received from or to be transmitted to the radio transceiver 110. The application processor 130 is configured to run the operating system of the portable electronic device 100 and run application programs installed in the portable electronic device 100. In the embodiments of the invention, the modem 120 and the application processor 130 may be designed as discrete chips with some buses or hardware interfaces coupled therebetween, or they may be integrated into a combo chip (i.e., a system on chip (SoC)), and the invention should not be limited thereto.

The subscriber identity card 140 may be a SIM, USIM, R-UIM or CSIM card, or the like and may typically contain user account information, an International Mobile Subscriber Identity (IMSI) and a set of SIM application toolkit (SAT) commands and may provide storage space for phone book contacts. The memory device 150 may be coupled to the modem 120 and application processor 130 and may store system data or user data.

The battery module 160 may comprise at least two batteries, such as the battery Bat_1 (e.g. the first battery) and the battery Bat_2 (e.g. the second battery), and the corresponding gauge circuits, such as the gauge circuit 161 (e.g. the first battery gauge circuit) coupled to the battery Bat_1 and the gauge circuit 162 (e.g. the second battery gauge circuit) coupled to the battery Bat_2. The batteries comprised in the battery module 160 may form a power supplying system of the portable electronic device 100, and each of the battery Bat_1 and the battery Bat_2 has a corresponding rated capacity (e.g. the battery Bat_1 may have a first rated capacity and the battery Bat_2 may have a second rated capacity).

The gauge circuit 161 may be configured to measure the battery voltage, charging current and discharging current of the battery Bat_1. The gauge circuit 161 may be further configured to measure a level of battery voltage and a level of charge of the battery Bat_1. In addition, the gauge circuit 161 may be further configured to count a service life of the battery Bat_1 and measure a temperature of the battery Bat_1. Similarly, the gauge circuit 162 may be configured to measure the battery voltage, charging current and discharging current of the battery Bat_2. The gauge circuit 162 may be further configured to measure a level of battery voltage and a level of charge of the battery Bat_2. In addition, the gauge circuit 162 may be further configured to count a service life of the battery Bat_2 and a temperature of the battery Bat_2.

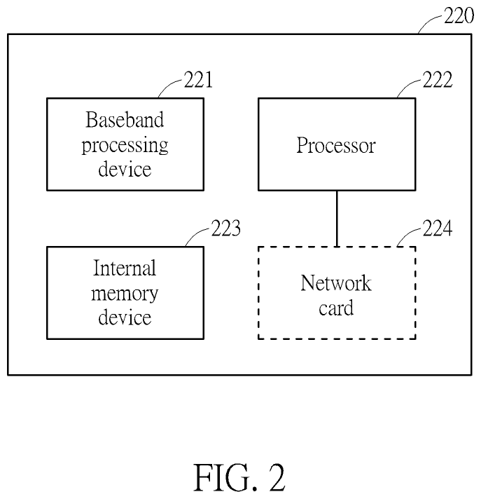

The gauge circuit 161 and the gauge circuit 162 may respectively report the measured or recorded results to the modem 120 or the processor of the modem 120 (e.g. report to the processor 222 shown in FIG. 2), for the processor to determining a State of Charge (SoC) of the battery module (or, the power supplying system). The SoC is a value indicating a level of charge of the battery module relative to a total capacity of the battery module. As an example, the SoC may be expressed as a percentage and the processor 222 may show the SoC on the User Interface so that the user gets the information regarding the current battery level.

According to some embodiments of the invention, the gauge circuit 161 and the gauge circuit 162 may be simply hardware circuits coupled to the batteries and the modem 120. In such implementations, property data of the battery Bat_1 and property data of the battery Bat_2 may be stored in the memory device 150 or the internal memory device (e.g. the internal memory device 223 shown in FIG. 2), and the proposed method for determining the SoC of the battery module 160 with modified or adjusted rated capacity, which will be discussed in more detailed in the following paragraphs, may be performed by the processor of the modem 120.

According to some other embodiments of the invention, the gauge circuit 161 may be comprised in a dedicated chip that is designed for gauging the battery Bat_1 and the gauge circuit 162 may be comprised in another dedicated chip that is designed for gauging the battery Bat_2. In such implementations, property data of the battery Bat_1 and property data of the battery Bat_2 may be stored in the internal memory device of the corresponding chip, and the proposed method for determining the SoC of the battery module 160 with modified or adjusted rated capacity may be performed by a processor (not shown) configured in either chip. In addition, in such implementations, there may be some buses or hardware interfaces coupled between the two chips for the chips to communicate with each other therethrough. Therefore, the proposed method is not limited to be performed by the processor inside the modem 120, and may also be performed by the processor comprised in one or more of the chips for battery gauging.

It should be noted that, in order to clarify the concept of the invention, FIG. 1 presents a simplified block diagram in which only the elements relevant to the invention are shown. For example, in some embodiments of the invention, the portable electronic device may further comprise some peripheral devices not shown in FIG. 1. In another example, in some embodiments of the invention, the portable electronic device may further comprise a central controller coupled to the modem 120 and the application processor 130. Therefore, the invention should not be limited to what is shown in FIG. 1.

In some embodiments of the invention, the portable electronic device is capable of supporting multiple radio access technologies (RATs) communications via the single-card structure as shown in FIG. 1. It should be noted that, although FIG. 1 shows a single-card application, the invention should not be limited thereto. For example, in some embodiments of the invention, the portable electronic device may comprise multiple subscriber identity cards to support the multi-RATs communications, in either a single-standby or a multiple-standby manner. In the multi-RATs communications applications, the modem, the radio transceiver and/or the antenna module may be shared by the subscriber identity card(s) and may have the capability of handling the operations of different RATs and processing the corresponding RF, IF or baseband signals in compliance with the corresponding communications protocols.

In addition, those who are skilled in this technology can still make various alterations and modifications based on the descriptions given above to derive the portable electronic devices comprising multiple radio transceivers and/or multiple antenna modules for supporting multi-RAT wireless communications without departing from the scope and spirit of this invention. Therefore, in some embodiments of the invention, the portable electronic device may be designed to support a multi-card application, in either a single-standby or a multiple-standby manner, by making some alterations and modifications.

It should be further noted that the subscriber identity card 140 may be dedicated hardware cards as described above, or in some embodiments of the invention, there may be virtual cards, such as individual identifiers, numbers, addresses, or the like which are burned in the internal memory device of the corresponding modem and are capable of identifying the portable electronic device. Therefore, the invention should not be limited to what is shown in the figures.

It should be further noted that in some embodiments of the invention, the portable electronic device may further support multiple IMSIs.

FIG. 2 shows an exemplary block diagram of a modem according to an embodiment of the invention. The modem 220 may be the modem 120 shown in FIG. 1 and may comprise at least a baseband processing device 221, a processor 222, an internal memory device 223 and a network card 224. The baseband processing device 221 may receive the IF or baseband signals from the radio transceiver 110 and perform IF or baseband signal processing. For example, the baseband processing device 221 may convert the IF or baseband signals into a plurality of digital signals, and process the digital signals, and vice versa. The baseband processing device 221 may comprise a plurality of hardware devices to perform signal processing, such as an analog-to-digital converter for ADC conversion, a digital-to-analog converter for DAC conversion, an amplifier for gain adjustment, a modulator for signal modulation, a demodulator for signal demodulation, an encoder for signal encoding, a decoder for signal decoding, and so on.

According to an embodiment of the invention, the baseband processing device 221 may be designed to have the capability of handling the baseband signal processing operations for different RATs and processing the corresponding IF or baseband signals in compliance with the corresponding communications protocols, so as to support the multi-RAT wireless communications. According to another embodiment of the invention, the baseband processing device 221 may comprise a plurality of sub-units, each being designed to have the capability of handling the baseband signal processing operations of one or more specific RATs and processing the corresponding IF or baseband signals in compliance with the corresponding communications protocols, so as to support the multi-RAT wireless communications. Therefore, the invention should not be limited to any specific way of implementation.

The processor 222 may control the operations of the modem 220. According to an embodiment of the invention, the processor 222 may be configured to execute the program codes of the corresponding software module of the modem 220. The processor 222 may maintain and execute the individual tasks, threads, and/or protocol stacks for different software modules. In an embodiment, a protocol stack may be implemented so as to respectively handle the radio activities of one RAT. However, it is also possible to implement more than one protocol stack to handle the radio activities of one RAT at the same time, or implement only one protocol stack to handle the radio activities of more than one RAT at the same time, and the invention should not be limited thereto.

The processor 222 may also read data from the subscriber identity card coupled to the modem, such as the subscriber identity card 140, and write data to the subscriber identity card. The internal memory device 223 may store system data and user data for the modem 220. The processor 222 may also access the internal memory device 223.

The network card 224 provides Internet access services for the portable electronic device. It should be noted that, although the network card 224 shown in FIG. 2 is configured inside of the modem, the invention should not be limited thereto. In some embodiments of the invention, the portable electronic device may also comprise a network card configured outside of the modem, or the portable electronic device may also be coupled to an external network card for providing Internet access services. In some embodiments of the invention, the network card 224 may be a virtual network card, instead of a tangible card, that is created by the operating system of the portable electronic device 100. Therefore, the invention should not be limited to any specific implementation method.

It should be noted that, in order to clarify the concept of the invention, FIG. 2 presents simplified block diagrams in which only the elements relevant to the invention are shown. Therefore, the invention should not be limited to what is shown in FIG. 2.

It should be further noted that in some embodiments of the invention, the modem may also comprise more than one processor and/or more than one baseband processing device. For example, the modem may comprise multiple processors and/or multiple baseband processing devices for supporting multi-RAT operations. Therefore, the invention should not be limited to what is shown in FIG. 2.

It should be further noted that in some embodiments of the invention, the baseband processing device 221 and the processor 222 may be integrated into one processing unit, and the modem may comprise one or multiple such processing units, for supporting multi-RAT operations. Therefore, the invention should not be limited to what is shown in FIG. 2.

In the conventional designs, the residual battery capacity perceived by the user usually drops rapidly and nonlinearly when the battery voltage is low and approaching the level to trigger a power-off of the mobile device and/or the portable electronic device. To solve this problem, in the embodiments of the invention, the processor 222 may determine the SoC of the battery module 160 with a modified or adjusted rated capacity. In this manner, the residual battery capacity to be presented to the user (e.g. the value of the SoC) will be decreased in a linearly manner, especially when the battery voltage is approaching the level to trigger a power-off of the portable electronic device 100.

Note that to simplify the descriptions, the processor 222 is utilized as a representative processor performing the proposed method in the following paragraphs. However, the invention is actually not limited thereto. As discussed above, the proposed method for determining the SoC of the battery module 160 with a modified or adjusted rated capacity may be also performed by a processor comprised in a chip which also comprises the battery gauge circuit, such as the gauge circuit 161 and/or 162 shown in FIG. 1. Therefore, the processor implementing the proposed method is not limited to the processor 222 comprised in the modem 120.

According to an embodiment of the invention, the proposed method for determining the SoC of the battery module comprised in the portable electronic device may conceptually comprise the following steps or operations performed by the processor (e.g. the processor 222) coupled to the battery module which comprises more than one battery (e.g. two batteries in the following embodiment):
Determining an adjusted rated capacity according to at least one of property data of the first battery, property data of the second battery and a system requirement, wherein the adjusted rated capacity may be smaller than a summation of the first rated capacity and the second rated capacity; and
Determining a State of Charge (SoC) which indicates a level of charge of the battery module relative to a total capacity of the battery module according to the level of charge of the battery module and the adjusted rated capacity.

In a first embodiment of the invention, the adjusted rated capacity may be determined according to the residual battery capacities of the battery modules with the consideration of power-off condition of the mobile device and/or the portable electronic device.

In a second embodiment of the invention, the adjusted rated capacity may be determined according to the residual battery capacities of the battery modules with the consideration of one or more system requirement. In an embodiment of the invention, a system requirement may be that when a current residual battery capacity of any one of the batteries in the battery module is too low as being lower than a threshold, stop the battery having the current residual battery capacity lower than the threshold from supplying power (that is, not configuring the battery having the current residual battery capacity lower than the threshold to supply power), and configuring the battery/batteries other than the one having the current residual battery capacity lower than the threshold to supply power. When the aforementioned condition of stop at least one battery from supplying power is met, the adjusted rated capacity may be determined, re-determined or updated only according to rated capacity and the residual battery capacity of the battery/batteries that is/are stilling supplying power.

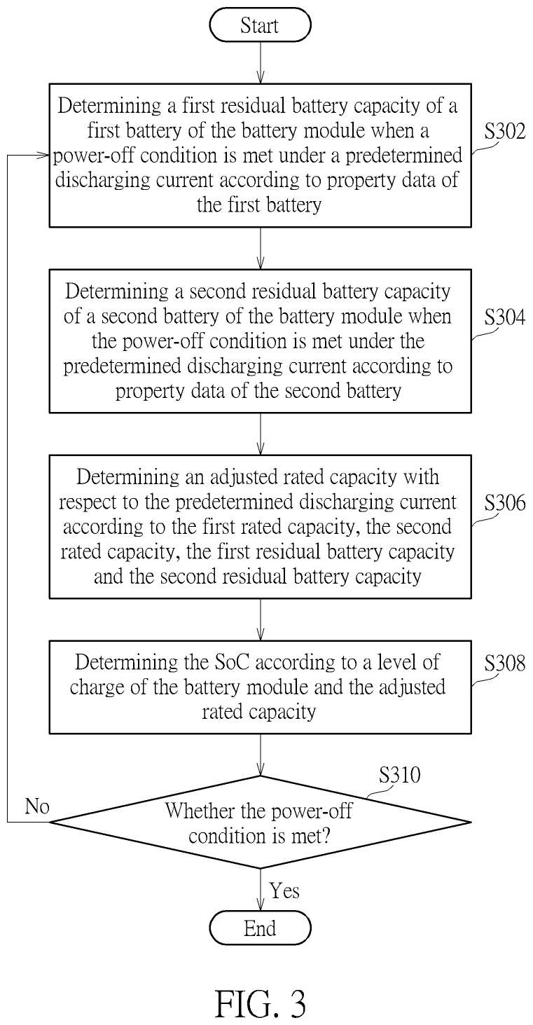

FIG. 3 shows an exemplary flow chart of a method for determining the SoC of the battery module comprised in the portable electronic device according to the first embodiment of the invention. The method comprises the following steps or operations performed by the processor (e.g. the processor 222) coupled to the battery module:
Step S302: determining a first residual battery capacity of a first battery of the battery module when a power-off condition is met under a predetermined discharging current according to property data of the first battery.
Step S304: determining a second residual battery capacity of a second battery of the battery module when the power-off condition is met under the predetermined discharging current according to property data of the second battery.
Step S306: determining an adjusted rated capacity with respect to the predetermined discharging current according to the first rated capacity, the second rated capacity, the first residual battery capacity and the second residual battery capacity.
Step S308: determining the SoC according to a level of charge of the battery module and the adjusted rated capacity. As described above, the SoC is a value indicating the level of charge of the battery module relative to a total capacity of the battery module.
Step S310: determining whether the power-off condition is met. If yes, it means that power-off of the portable electronic device is required and the process is ended. If no, Step S302 may be returned to keep updating the value of adjusted rated capacity and the SoC according to the latest battery condition (e.g. the latest levels of battery voltages, the latest levels of charge of the batteries, the latest discharging current, or the likes).

In an embodiment of the invention, since the discharging current and the level of charge of the battery module may change all the time, the adjustment or the update of the rated capacity as well as the determination of the SoC may be repeatedly performed every time when a predetermined amount of change (e.g. 0.5%˜1%) in the level of charge of the battery module or in the SoC is achieved.

According to an embodiment of the invention, to facilitate determination of the residual battery capacity of a battery in the battery module when the power-off condition is met under a predetermined discharging current, the processor 222 may further find out a no-load voltage, which will trigger a power-off of the portable electronic device 100, of one of the batteries when the predetermined discharging current is conducted. As an example, the processor 222 may try to find out a no-load voltage of the battery Bat_1 that will trigger a power-off of the portable electronic device 100 when the predetermined discharging current is conducted, and take the residual battery capacity corresponding to the found no-load voltage of the battery Bat_1 as the first residual battery capacity to be determined in step S302. In addition, the processor 222 may further take the residual battery capacity of the battery Bat_2 corresponding to a predetermined no-load voltage of the battery Bat_2 that is equal to the found no-load voltage of the battery Bat_1 as the second residual battery capacity to be determined in step S304.

According to an embodiment of the invention, the no-load voltage of a battery is measured under a no-load condition of the battery, that is, no loading is connected to the battery, and said triggering of the power-off of the portable electronic device (e.g. when the power-off condition of the portable electronic device 100 is met) is that when the predetermined discharging current is conducted at the found no-load voltage of the corresponding battery, a battery voltage of said battery is reduced to a level as low as the one to trigger the power-off of the portable electronic device.

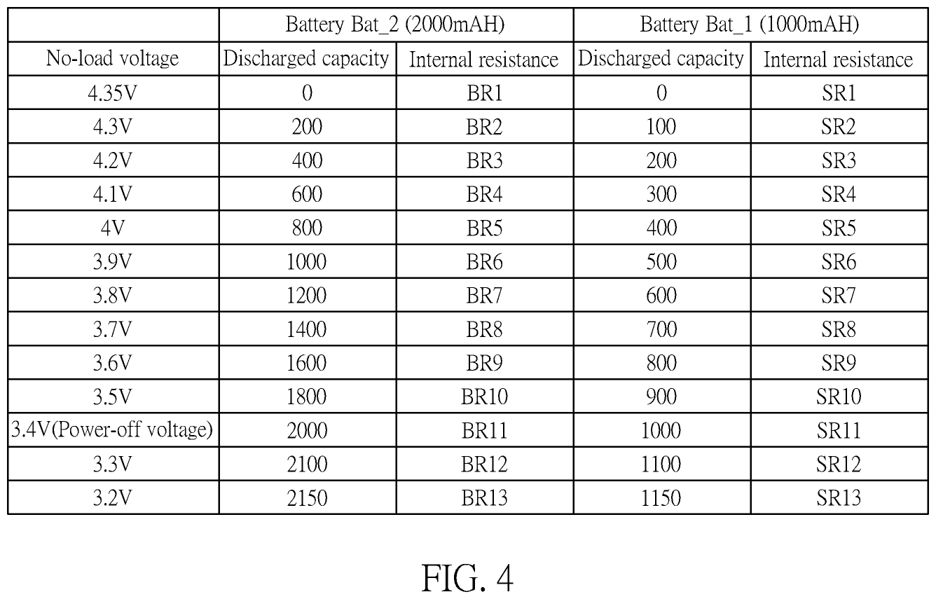

FIG. 4 is a table showing the exemplary property data of the batteries Bat_1 and Bat_2 according to an embodiment of the invention. According to an embodiment of the invention, the property data of a battery may at lease comprise a rated capacity of the battery, a plurality of no-load voltages, the corresponding amounts of reduced capacity (e.g. the discharged capacity) when the battery is discharged under a predetermined discharging current and the corresponding internal resistance of the battery. Note that the data shown in FIG. 4 may be measured under a predetermined temperature condition (for example, in a predetermined battery temperature) and under a predetermined service life condition.

In FIG. 4, the rated capacity of the battery Bat_2 is 2000 milliamp Hour (mAH), the rated capacity of the battery Bat_1 is 1000 mAH, and the property data of the batteries Bat_1 and Bat_2 with respect to the no-load voltages 4.35V, 4.3V, 4.2V, . . . 3.4V, 3.3V and 3.2V is shown, where the no-load voltage of a battery is measured under a no-load condition of the corresponding battery.

Taking the first row of property data as an example, the no-load voltage of 4.35V is obtained. The first no-load voltage may be measured when the batteries Bat_1 and Bat_2 of the battery module are fully charged. For the fully charged no-load voltage 4.35V, since the discharging current is not yet conducted, the discharged capacity, which is an accumulated value, is 0.

Taking the second row of property data of battery Bat_1 as an example, suppose that a first discharging current I is conducted for a predetermined period of time, such as 1 hour, after the discharging is stopped for a period of time, the no-load voltage, the amount of reduced capacity and internal resistance of the battery Bat_1 are measured. In this example, the measured no-load voltage is 4.3V, the measured discharged capacity is 100 mAH, and the corresponding internal resistance of the battery Bat_1 is SR2.

Similarly, for the battery Bat_2, suppose that a second discharging current 2*I is conducted for a predetermined period of time, such as 1 hour, after the discharging is stopped for a period of time, the no-load voltage, the amount of reduced capacity and internal resistance of the battery Bat_2 are measured. In this example, the measured no-load voltage is 4.3V, the measured discharged capacity is 200 mAH, and the corresponding internal resistance of the battery Bat_2 is BR2. Note that the property data of the battery Bat_1 and the property data of the battery Bat_2 are measured separately and independently, but they are shown together in FIG. 4 for simplicity.

The processor 222 may find out a no-load voltage, which will trigger the power-off of the portable electronic device 100, of one of the batteries when a predetermined discharging current is conducted. Taking the first discharging current I and the second discharging current 2*I as an example, the processor 222 may find out a no-load voltage that will make the battery voltage of one battery to be reduced to the power-off voltage of the portable electronic device 100 when a predetermined discharging current, e.g. 3*I or a value approaching 3*I, is conducted in the battery module 160, where the predetermined discharging current may be a combination of the first discharging current I and the second discharging current 2*I or a value approaching the combination of the first discharging current I and the second discharging current 2*I.

The processor 222 may find out the no-load voltage of a predetermined battery to trigger the power-off of the portable electronic device 100 based on the following equation Eq. (1):

$$V\_bat = OC V - I\_Bat * R\_Bat \qquad Eq . ( 1 )$$

where the I_Bat is the discharging current conducted by the predetermined battery, the R_Bat is the internal resistance of the predetermined battery, the V_bat is the battery voltage obtained after the discharging current is conducted and the OCV is a no-load voltage of the predetermined battery. Note that the values of I_Bat, R_Bat and OCV may be obtained from the property data of the predetermined battery as the data shown in FIG. 4

Suppose that a power-off condition of the portable electronic device 100 is met when the battery voltage of any battery in the battery module reaches a power-off voltage, and in this embodiment, the power-off voltage is set to 3.4V, the processor 222 may set the voltage V_bat to 3.4V, rearrange equation Eq. (1) and find out the no-load voltage OCV of the predetermined battery to trigger the power-off of the portable electronic device 100 based on the following equation Eq. (2):

$$3.4 = OC V - I\_Bat * R\_Bat \qquad Eq . ( 2 )$$

Suppose that the no-load voltage OCV found by the processor 222 based on the property data of the battery Bat_1 is 3.6V, it means that when the current battery voltage of the battery Bat_1 is 3.6V, the battery voltage of the battery Bat_1 will be reduced to 3.4V (i.e. the power-off voltage) when the predetermined discharging current 3*I is conducted by the battery module 160 (that is, for the battery Bat_1, the first discharging current of I is conducted).

As shown in FIG. 4, at the 3.6V no-load voltage of the battery Bat_1, the discharged capacity of the battery Bat_1, which is an accumulated value, is 800 mAH. Therefore, when the 3.4V power-off condition is met under the predetermined discharging current, the residual battery capacity corresponding to the found no-load voltage 3.6V of the battery Bat_1 is (1000-800)=200 mAH. Here, the term “the residual battery capacity” may refer to the battery capacity that is still contained in the corresponding battery, and the residual battery capacity determined when a power-off condition is met may also mean that the battery capacity contained in the corresponding battery and cannot be discharged (since the portable electronic device has to be powered off).

Similarly, at the 3.6V no-load voltage of the battery Bat_2, the accumulated discharged capacity of the battery Bat_2 is 1600 mAH. Therefore, when the 3.4V power-off condition is met under the predetermined discharging current, since the portable electronic device has to be powered off no matter whether the battery voltage of the battery Bat_2 is reduced to 3.4V, the residual battery capacity corresponding to a predetermined no-load voltage of the battery Bat_2 that is equal to the found no-load voltage 3.6V is (2000-1600)-400 mAH.

Therefore, the summation of the residual battery capacity corresponding to the found no-load voltage 3.6V of the battery Bat_1 (e.g. the first residual battery capacity) and the residual battery capacity corresponding to a predetermined no-load voltage of the battery Bat_2 (e.g. the second residual battery capacity) is (200+400)=600 mAH.

Note that the processor 222 is configured to find out the no-load voltage OCV of any battery in the battery module that will trigger the power-off of the portable electronic device 100. That is, as long as the battery voltage of anyone battery in the battery module reaches the preset power-off voltage (e.g. 3.4V), the power-off condition is met. Therefore, it is not necessary for the battery voltage of all batteries in the battery module to reach the preset power-off voltage when the power-off condition is met.

Referring back to FIG. 3, according to an embodiment of the invention, the adjusted rated capacity in Step S306 may be determined by subtracting a summation of the first residual battery capacity and the second residual battery capacity from a summation of the first rated capacity and the second rated capacity. Continuing the example as discussed above, the adjusted rated capacity would be: (2000+1000−600)=2400 mAH.

Since there may be a total residual battery capacity of 600 mAH that is not discharged when the power-off condition is met, in the embodiments of the invention, the processor 222 reduces the total residual battery capacity from the total rated capacity of the battery module 160, so as to correct the total rated capacity of the battery module 160 to an actual value, for the SoC to reveal the true condition of the battery module 160.

Note that in the conventional designs, the total rated capacity of the battery module having the first battery and the second battery as an example may be simply set as the summation of the first rated capacity and the second rated capacity. Therefore, in the conventional designs, the residual battery capacity perceived by the user usually drops rapidly and nonlinearly when the battery voltage is low and approaching the level to trigger a power-off of the mobile device and/or the portable electronic device. Different from the conventional designs, the total rated capacity of the battery module is flexibly adjusted with respect to the predetermined discharging current as illustrated in Step S306, therefore, the value of the SoC will be decreased in a linearly manner.

Referring back to FIG. 3, according to an embodiment of the invention, when determining the SoC according to a level of charge of the battery module and the adjusted rated capacity in Step S308, the processor 222 may respectively obtain the current level of charge of the battery Bat_1 (e.g. the current battery level of the battery Bat_1) measured by the gauge circuit 161 and obtain the current level of charge of the battery Bat_2 (e.g. the current battery level of the battery Bat_2) measured by the gauge circuit 162, and then obtain the level of charge of the battery module 160, which may be a summation of the current battery level of the battery Bat_1 and the current battery level of the battery Bat_2. The obtained level of charge of the battery module 160 is then divided by the adjusted rated capacity obtained in Step S306 to obtain the SoC expressed as a percentage.

Since the SoC is obtained based on the adjusted rated capacity obtained in Step S306, the SoC reveals the true condition of the battery module 160 and the value of the SoC will be decreased in a linearly manner under a fixed loading condition. Different from the conventional designs, even when the battery voltage is approaching the level to trigger a power-off of the portable electronic device 100, as long as the fixed loading condition remains, the value of the SoC will still be decreased in a linearly manner.

In addition, since the battery property changes as the discharging current changes, the environment temperature or the battery temperature changes, and/or the service life of the battery changes (that is, due to aging of the battery), in some other aspects of the invention, the processor 222 may determine a plurality of adjusted rated capacities with respect to different levels of discharging current according to the first rated capacity, the second rated capacity, and the first residual battery capacity and the second residual battery capacity determined under said different levels of discharging current.

As an example, in an embodiment of the invention, the processor 222 may determine the adjusted rated capacity with respect to a different discharging current, which is different from the aforementioned predetermined discharging current, according to the first rated capacity (which may be a fixed value), the second rated capacity (which may be also a fixed value), and the first residual battery capacity and the second residual battery capacity determined under said different discharging current. The way to determine the first residual battery capacity and the second residual battery capacity under said different discharging current is similar to the case under the predetermined discharging current as introduced above, therefore, reference may be made to the embodiments discussed above, and details are omitted here for brevity.

Similarly, the processor 222 may determine a plurality of adjusted rated capacities with respect to one or more discharging currents under different temperatures according to the first rated capacity, the second rated capacity, and the first residual battery capacity and the second residual battery capacity determined under said different temperatures.

As an example, in an embodiment of the invention, for the aforementioned predetermined discharging current, the processor 222 may update the adjusted rated capacity with respect to the predetermined discharging current according to the first rated capacity, the second rated capacity, and the first residual battery capacity and the second residual battery capacity determined under a predetermined temperature of the battery module when a temperature of the battery module changes.

Similarly, the processor 222 may determine a plurality of adjusted rated capacities with respect to one or more discharging currents under different service life according to the first rated capacity, the second rated capacity, and the first residual battery capacity and the second residual battery capacity determined under said different service life.

As an example, in an embodiment of the invention, for the aforementioned predetermined discharging current, the processor 222 may update the adjusted rated capacity with respect to the predetermined discharging current according to the first rated capacity, the second rated capacity, and the first residual battery capacity and the second residual battery capacity determined under a predetermined service life of the battery module when a service life of the battery module changes.

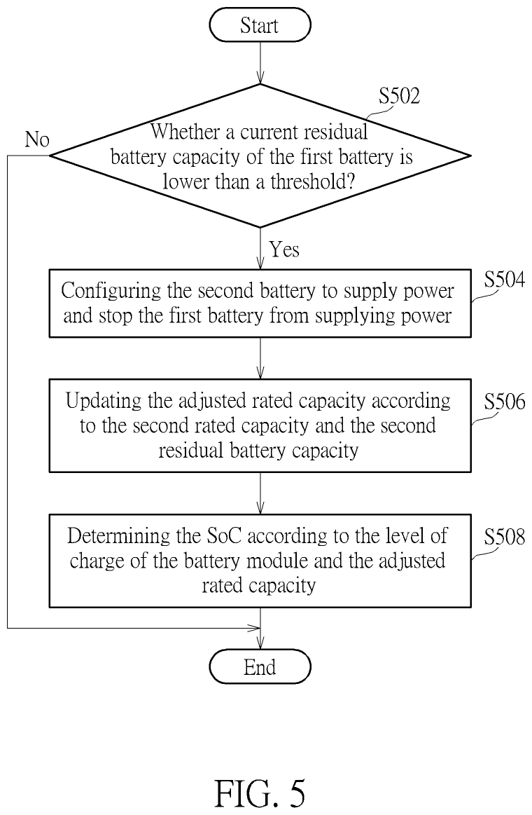

FIG. 5 shows an exemplary flow chart of a method for determining the SoC of the battery module comprised in the portable electronic device according to the second embodiment of the invention. The method comprises the following steps or operations performed by the processor (e.g. the processor 222) coupled to the battery module:
Step S502: determining whether a current residual battery capacity of the first battery is lower than a threshold. In the embodiments of the invention, the threshold may be flexibly set. As an example, the threshold may be set to a value indicating that the corresponding battery is in a low-battery status based on the property data of the corresponding battery. If yes, step S504 is performed. If no, the process may be ended.
Step S504: configuring the second battery to supply power and stop the first battery from supplying power when the current residual battery capacity of the first battery is lower than the threshold.
Step S506: updating the adjusted rated capacity for a condition of only the second battery is supplying power according to the second rated capacity and the second residual battery capacity determined under the condition of only the second battery is supplying power.
Step S508: determining (or, re-determining) the SoC according to the level of charge of the battery module and the adjusted rated capacity. In this embodiment, the level of charge of the battery module is the level of charge of the second battery, and the adjusted rated capacity in step S506 may be updated by subtracting the second residual battery capacity from the second rated capacity of the second battery, and the second residual battery capacity utilized in step S506 may be obtained based on the similar concept as illustrated above in step S302 or S304. That is, the second residual battery capacity utilized in step S506 may be the one determined when a power-off condition is met under a predetermined discharging current.

Note that in an alternative embodiment of the invention, the adjusted rated capacity in step S506 may also be updated based on only the second rated capacity of the second battery (that is, without considering the second residual battery capacity determined when a power-off condition is met).

In yet other embodiments of the invention, another system requirement may be that when a current residual battery capacity of any one of the batteries in the battery module is too low as being lower than a threshold, the portable electronic device 100 is powered off, to avoid shortening the life of the batteries due to excessive discharge.

Therefore, in the embodiments of the invention, the property data of all batteries in the battery module as well as one or more system requirement may be integrated and considered when determining the operation of the battery supply system (e.g. whether to supply power or not) and estimating the residual battery capacity and the actual total capacity (e.g., the adjusted rated capacity with the consideration of residual battery capacities that cannot be discharged when the portable electronic device has to be powered off in the first embodiment and the overall rated capacity with the consideration of only the serving battery/batteries in the second embodiment) of the power supplying system, so as to achieve the results of protecting the batteries (e.g. extending the battery life) in the battery module and revealing the true condition of the battery module to the user through the value of the SoC which will be decreased linearly.

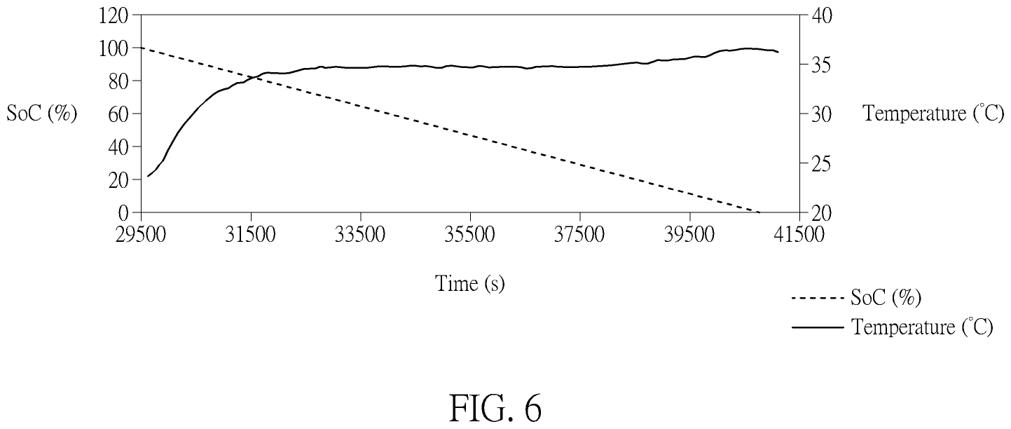

FIG. 6 is a schematic diagram showing the SoC determined by applying the proposed method under different temperature and service life conditions according to an embodiment of the invention. In the resulting SoC shown in FIG. 6, since the adjusted rated capacity is continuously updated when the temperature and/or service life (such as the ‘Time(s)’ shown in the X-axis) changes, the value of the SoC is decreased linearly as long as the fixed loading condition remains, and no sudden drop or nonlinear curve is presented.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A portable electronic device, comprising:
a battery module, comprising a first battery having a first rated capacity and a second battery having a second rated capacity; and
a processor, coupled to the battery module and configured to perform operations comprising:
determining an adjusted rated capacity according to at least one of property data of the first battery, property data of the second battery and a system requirement, wherein the adjusted rated capacity is smaller than a summation of the first rated capacity and the second rated capacity; and
determining a State of Charge (SoC) which indicates a level of charge of the battery module relative to a total capacity of the battery module according to the level of charge of the battery module and the adjusted rated capacity.

2. The portable electronic device of claim 1, wherein the processor is further configured to perform operations comprising:
determining a first residual battery capacity of the first battery when a power-off condition is met under a predetermined discharging current according to the property data of the first battery; and
determining a second residual battery capacity of the second battery when the power-off condition is met under the predetermined discharging current according to the property data of the second battery, and
when determining the adjusted rated capacity, the processor is further configured to perform operation comprising:
determining the adjusted rated capacity with respect to the predetermined discharging current according to the first rated capacity, the second rated capacity, the first residual battery capacity and the second residual battery capacity.

3. The portable electronic device of claim 2, wherein the adjusted rated capacity is determined by subtracting a summation of the first residual battery capacity and the second residual battery capacity from the summation of the first rated capacity and the second rated capacity.

4. The portable electronic device of claim 1, further comprising:
a first battery gauge circuit, coupled to the first battery and configured to measure a level of charge of the first battery; and
a second battery gauge circuit, coupled to the second battery and configured to measure a level of charge of the second battery,
wherein the level of charge of the battery module is a summation of the level of charge of the first battery and the level of charge of the second battery.

5. The portable electronic device of claim 2, wherein the processor is further configured to perform operation comprising:
determining the adjusted rated capacity with respect to a different discharging current according to the first rated capacity, the second rated capacity, and the first residual battery capacity and the second residual battery capacity determined under said different discharging current.

6. The portable electronic device of claim 2, wherein the processor is further configured to perform operations comprising:
determining whether a current residual battery capacity of the first battery is lower than a threshold;
configuring the second battery to supply power and stop the first battery from supplying power when the current residual battery capacity of the first battery is lower than the threshold;
updating the adjusted rated capacity for a condition of only the second battery is supplying power according to the second rated capacity and the second residual battery capacity determined under the condition of only the second battery is supplying power; and
re-determining the SoC according to the level of charge of the battery module and the adjusted rated capacity,
wherein the level of charge of the battery module is a level of charge of the second battery.

7. The portable electronic device of claim 2, wherein the processor is further configured to perform operation comprising:
updating, when a service life of the battery module changes, the adjusted rated capacity with respect to the predetermined discharging current according to the first rated capacity, the second rated capacity, and the first residual battery capacity and the second residual battery capacity determined under a predetermined service life of the battery module.

8. The portable electronic device of claim 2, wherein the processor is further configured to perform operation comprising:
updating, when a temperature of the battery module changes, the adjusted rated capacity with respect to the predetermined discharging current according to the first rated capacity, the second rated capacity, and the first residual battery capacity and the second residual battery capacity determined under a predetermined temperature of the battery module.

9. The portable electronic device of claim 2, wherein the processor is further configured to perform operation comprising:
finding out a no-load voltage of the first battery that will trigger a power-off of the portable electronic device when the predetermined discharging current is conducted,
wherein the no-load voltage of the first battery is measured under a no-load condition of the first battery and the first residual battery capacity of the first battery is a residual battery capacity corresponding to the found no-load voltage of the first battery.

10. The portable electronic device of claim 9, wherein the second residual battery capacity of the second battery is a residual battery capacity corresponding to a predetermined no-load voltage of the second battery that is equal to the found no-load voltage of the first battery.

11. The portable electronic device of claim 4, wherein the first battery gauge circuit is comprised in a first chip and the second battery gauge circuit is comprised in a second chip, and the processor is comprised in either the first chip or the second chip.

12. A method for determining a State of Charge (SoC) of a battery module comprised in a portable electronic device, wherein the battery module comprises a first battery having a first rated capacity and a second battery having a second rated capacity, and the method comprises:
determining an adjusted rated capacity according to at least one of property data of the first battery, property data of the second battery and a system requirement, wherein the adjusted rated capacity is smaller than a summation of the first rated capacity and the second rated capacity; and
determining a State of Charge (SoC) which indicates a level of charge of the battery module relative to a total capacity of the battery module according to the level of charge of the battery module and the adjusted rated capacity.

13. The method of claim 12, further comprising:
determining a first residual battery capacity of the first battery when a power-off condition is met under a predetermined discharging current according to the property data of the first battery; and
determining a second residual battery capacity of the second battery when the power-off condition is met under the predetermined discharging current according to the property data of the second battery, and
when determining the adjusted rated capacity, the method further comprising:
determining the adjusted rated capacity with respect to the predetermined discharging current according to the first rated capacity, the second rated capacity, the first residual battery capacity and the second residual battery capacity.

14. The method of claim 13, wherein the adjusted rated capacity is determined by subtracting a summation of the first residual battery capacity and the second residual battery capacity from the summation of the first rated capacity and the second rated capacity, and the level of charge of the battery module is a summation of a level of charge of the first battery and a level of charge of the second battery.

15. The method of claim 13, further comprising:
determining the adjusted rated capacity with respect to a different discharging current according to the first rated capacity, the second rated capacity, and the first residual battery capacity and the second residual battery capacity determined under said different discharging current.

16. The method of claim 13, further comprising:
determining whether a current residual battery capacity of the first battery is lower than a threshold;
configuring the second battery to supply power and stop the first battery from supplying power when the current residual battery capacity of the first battery is lower than the threshold;
updating the adjusted rated capacity for a condition of only the second battery is supplying power according to the second rated capacity and the second residual battery capacity determined under the condition of only the second battery is supplying power; and
re-determining the SoC according to the level of charge of the battery module and the adjusted rated capacity,
wherein the level of charge of the battery module is a level of charge of the second battery.

17. The method of claim 13, further comprising:
updating the adjusted rated capacity with respect to the predetermined discharging current according to the first rated capacity, the second rated capacity, and the first residual battery capacity and the second residual battery capacity determined under a predetermined service life of the battery module when a service life of the battery module changes.

18. The method of claim 13, further comprising:
updating the adjusted rated capacity with respect to the predetermined discharging current according to the first rated capacity, the second rated capacity, and the first residual battery capacity and the second residual battery capacity determined under a predetermined temperature of the battery module when a temperature of the battery module changes.

19. The method of claim 13, further comprising:
finding out a no-load voltage of the first battery that will trigger a power-off of the portable electronic device when the predetermined discharging current is conducted,
wherein the no-load voltage of the first battery is measured under a no-load condition of the first battery and the first residual battery capacity of the first battery is a residual battery capacity corresponding to the found no-load voltage of the first battery.

20. The method of claim 19, wherein the second residual battery capacity of the second battery is a residual battery capacity corresponding to a predetermined no-load voltage of the second battery that is equal to the found no-load voltage of the first battery, and said triggering of the power-off of the portable electronic device is that when the predetermined discharging current is conducted at the found no-load voltage of the first battery, a battery voltage of the first battery is reduced to a level to trigger the power-off of the portable electronic device.
